(19) United States
(12) Patent Application Publication
(10) Pub. No.: US 2014/0117199 A1
(43) Pub. Date: May 1, 2014

(54) SUPPORT MECHANSIM FOR DEVICE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: YU-TAI LIU, New Taipei (TW); CHIN-CHUNG FU, New Taipei (TW); CHIH-YUAN CHANG, New Taipei (TW); JUN-HAO WANG, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 13/971,945

(22) Filed: Aug. 21, 2013

(30) Foreign Application Priority Data
Oct. 30, 2012 (CN) 2012104234199

(51) Int. Cl. H05K 7/16

(52) U.S. Cl. CPC H05K 7/16
USPC 248/688

(57) ABSTRACT

A foldable supporting mechanism includes at least one hinge secured to a device, a bracket rotatably fixed to the device by the at least one hinge, and an elastic assembly secured to the at least one hinge. The supporting mechanism provides an elastic force to retain the bracket at an angle with the device when the bracket is unfolded. When the bracket is folded, the elastic assembly restores to continue urging the bracket to be fully retracted against the device. The at least one buffering assembly impedes the free rotation of the bracket relative to the device when the bracket is being unfolded and when it is being folded. An electronic device having the supporting mechanism is also provided.

### BACKGROUND

1. Technical Field

The present disclosure relates to support mechanisms, and more particularly, to a support mechanism for an electronic device.

2. Description of Related Art

Electronic devices, such as tablet computers, include a main body and a support mechanism for supporting the main body on a support surface. The support mechanism is rotatably secured to a back surface of the main body. A torsion spring is arranged between the main body and the support mechanism. When the support mechanism is folded by an external force, the torsion spring is deformed to retain the support mechanism in the folded state. When the support mechanism is unfolded by an external force, the torsion spring restores to retain the support mechanism at a predetermined angle with the main body. However, when the support mechanism is to be put into the folded state, the deformed torsion spring may cause the support mechanism to snap shut, which may break the support mechanism, and possibly hurt the user.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a partial perspective view of an electronic device in accordance with an embodiment.

FIG. 2 is similar to FIG. 1, but viewed from another aspect.

FIG. 3 is a disassembled view of the electronic device in FIG. 2, the electronic device including a support mechanism.

FIG. 4 is a partially disassembled view of the support mechanism in FIG. 3, the support mechanism including a buffering assembly.

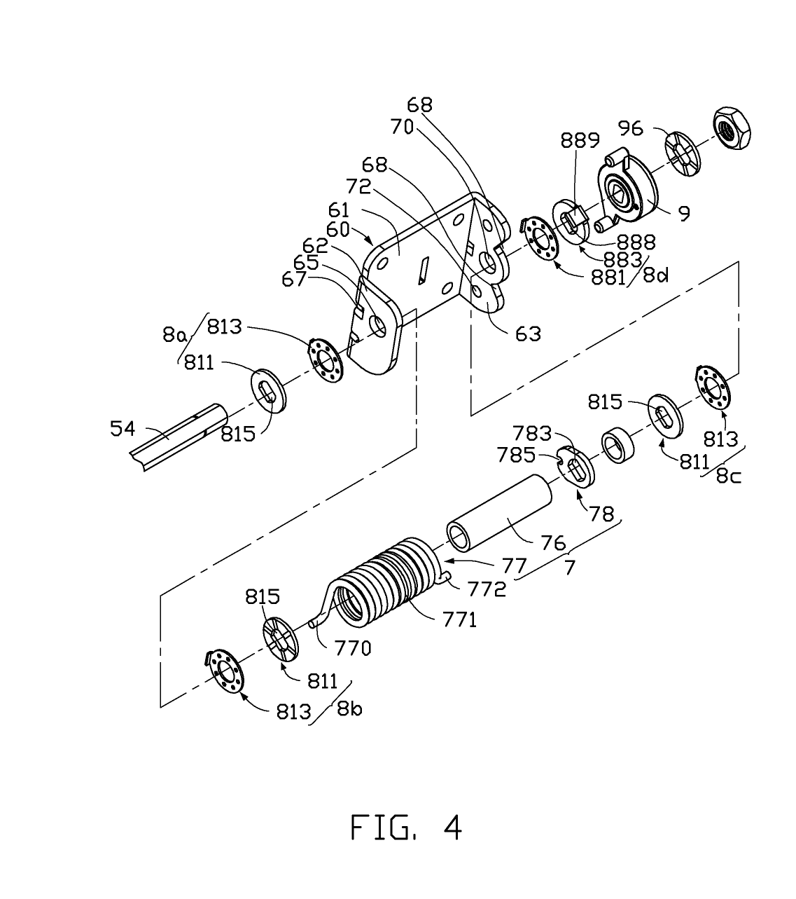

FIG. 5 is a disassembled view of the buffering assembly in FIG. 4.

FIG. 6 is similar to FIG. 5, but viewed from another aspect.

FIG. 7 is a cross section view of the buffering assembly in FIG. 4.

FIG. 8 is a partially assembled view of the support mechanism in FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

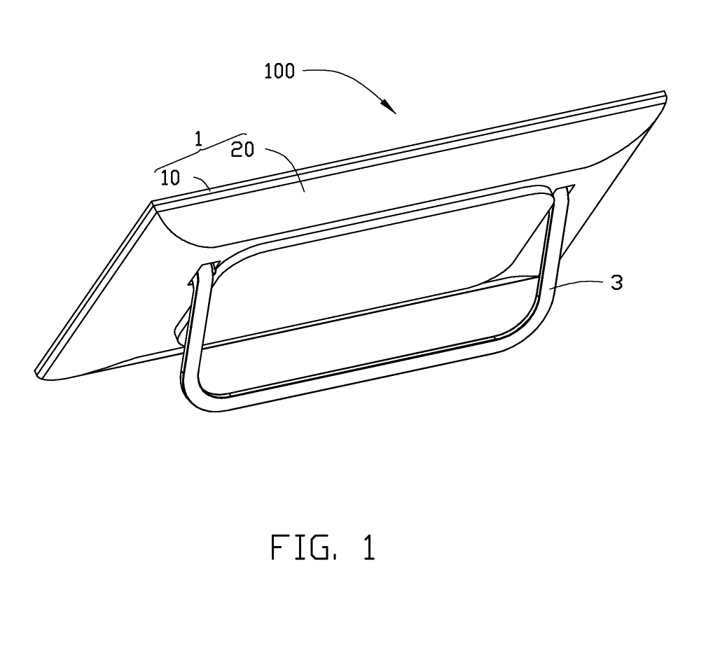

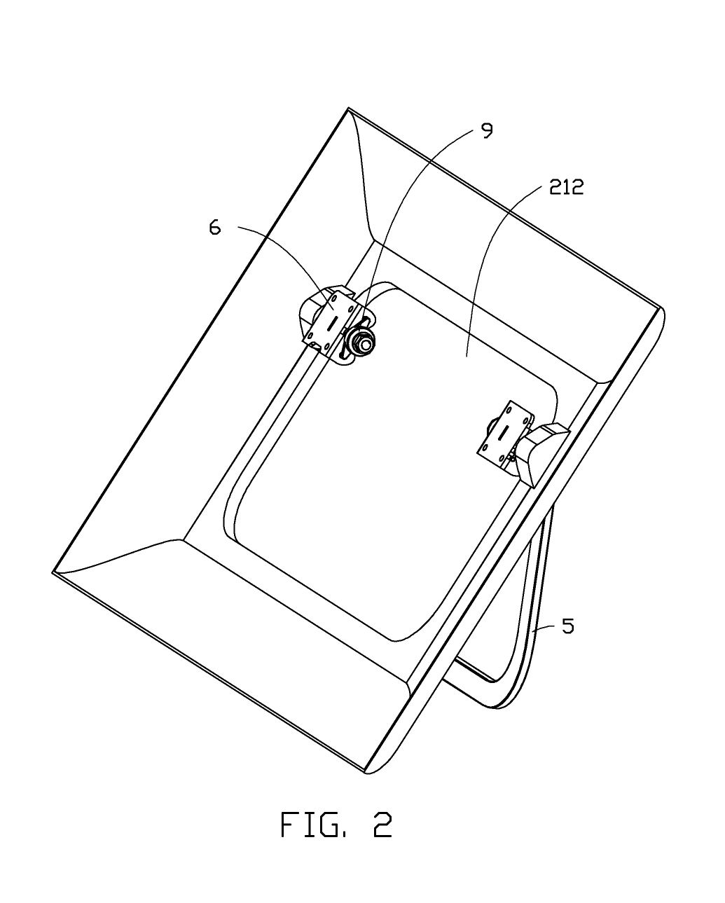

Referring to FIGS. 1 and 2, an electronic device 100 in accordance with an embodiment is shown. The electronic device 100 includes a main body 1 and a support mechanism 3 for supporting the main body 1 on a supporting surface, such as a desk. The electronic device 100 can be a PDA, a mobile telephone, a tablet computer, or the like. The electronic device 100 in the embodiment is a tablet computer.

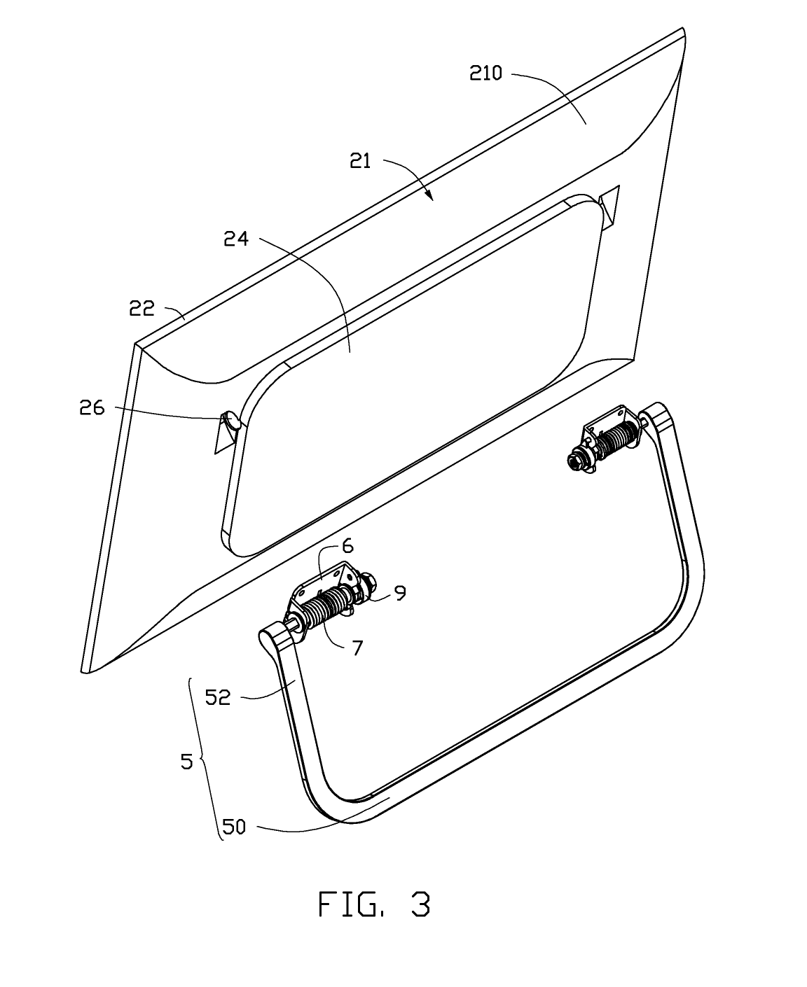

The main body 1 is substantially rectangular, and includes a front case 10 and a rear case 20. The front case 10 engages with the rear case 20 to define a receiving space (not label) for receiving circuit board, DVD driver and other electronic components of the electronic device 100. A display (not shown) is mounted to the front case 10. Referring also to FIG. 3, a substantially rectangular protruding block 24 is secured to a back surface 210 of the rear case 20 opposite to the front case 10. When viewed from the back surface 210, the protruding block 24 protrudes from the back surface 210; while viewed from an inner surface 212 (see FIG. 2) of the rear case 20 opposite to the back surface 210, the protruding blocking 24 is a hollow structure, recessed from the inner surface 212 to define a cavity. The rear case 20 further defines two mounting holes 26 communicating with the receiving space. The mounting holes 26 are symmetrically arranged at opposite sides of the protruding block 24. The mounting holes 26 are aligned parallel to and adjacent to the top edge 22 of the rear case 20.

The support mechanism 3 includes a bracket 5, two hinges 6, two elastic assemblies 7, and two buffering assemblies 9. The bracket 5 is rotatably secured to the main body 1 by the hinges 6, and is foldable onto the back surface 210 of the rear case 20. The elastic assemblies 7 are secured to the hinges 6. The elastic assemblies 7 are capable of being deformed to retain the bracket 5 in a folded state on the back surface 210, and is capable of restoring the bracket 4 to a predetermined support angle with the back surface 210. The buffering assemblies 9 are secured to the hinges 6, and are used for buffering the bracket 4 when forced by the deformed elastic assemblies 7.

The bracket 5 is substantially U-shaped, and is capable of being folded on the back surface 210. When the bracket 5 is folded, the bracket 5 is coplanar with and surrounds a portion of the protruding block 24. The bracket 5 includes a base 50 and two cantilevers 52 extending from opposite ends of the base 50.

The hinges 6 are secured to ends of the cantilevers 52 away from the base 50 and face each other. Each hinge 6 includes a shaft 54 fixed to a cantilever 52 and a pivot bracket 60 rotatably secured to the shaft 54. The shaft 54 is substantially columnar. Opposite sides of a cross section of the shaft 54 are removed to form two parallel flat end portions 540, the cross section of the shaft 54 then being substantially oval. The pivot bracket 60 includes a fixing plate 61 and two mounting plates 62, 63. The fixing plate 61 is fixed to the inner surface 212. The mounting plates 62, 63 extend from opposite ends of the fixing plate 61. The mounting plates 62, 63 define two round holes 65, 70 for rotatably receiving the shaft 54. An end of the mounting plate 62 adjacent to the fixing plate 61 defines a first latching hole 67. The mounting plate 63 defines two limiting holes 72. The limiting holes 72 are aligned with the round hole 70 and are symmetrical relative to the round hole 70. An end of the mounting plate 63 away from the fixing plate 61 is substantially crenellated, and defines two recesses 68.

Each hinge 6 further includes a number of friction assemblies 8a, 8b, 8c and a positioning assembly 8d. The friction assemblies 8a, 8b, 8c and the positioning assembly 8d are sleeved on the shaft 54. The friction assemblies 8a and 8b are mounted to opposite sides of the mounting plate 62. The friction assemblies 8c and the positioning assembly 8d are mounted to opposite sides of the mounting plate 63. Each friction assembly includes a first shim 811 and a second shim 813. The first shim 811 defines a through hole 815 to fit the shaft 54, to prevent the first shim 811 from rotating around the shaft 54. The second shim 813 is secured to the mounting plate 62 and defines a round hole for rotatably receiving the shaft 54, whereby the second shim 813 is capable of rotating with the pivot bracket 60 around the shaft 54. The positioning assembly 8d includes a second shim 881 fixed to the mounting plate 63 and a positioning member 883. The structure of the second shim 881 and the structure of the first shim 811 are the same. The second shim 881 is sleeved on the shaft 54 and is rotatable around the shaft 54. The positioning member 883 defines a positioning hole 888 to fit the shaft 54, to prevent the positioning member 883 from rotating around the shaft 54. A positioning post 889 is secured to a rim of the positioning member 883. The positioning post 889 is capable of sliding between the two recesses 68 defined on the mounting plate 63. As the positioning member 883 rotates with the shaft 54, when the positioning post 889 slides between the recesses 68, the shaft 54 is positioned in two different orientations relative to the pivot bracket 60.

Each elastic assembly 7 includes a sleeve 76, an elastic member 77, and a limiting member 78. The sleeve 76 is substantially hollow and columnar. The sleeve 76 is arranged between the mounting plates 62, 63 and is sleeved on the shaft 54. The limiting member 78 is arranged between the sleeve 76 and the friction assembly 8c. The limiting member 78 defines an engaging hole 783 receiving the shaft 54, to prevent the limiting member 78 from rotating around the shaft 54. The limiting member 78 further defines a second latching hole 785 spaced apart from the engaging hole 783. The elastic member 77 in the embodiment is a torsion spring 77, includes a spiral spring 771, and two arms 770, 772 extending from opposite ends of the spiral spring 771. The arm 770 is mounted to the first latching hole 67, and the arm 772 is mounted to the second latching hole 785.

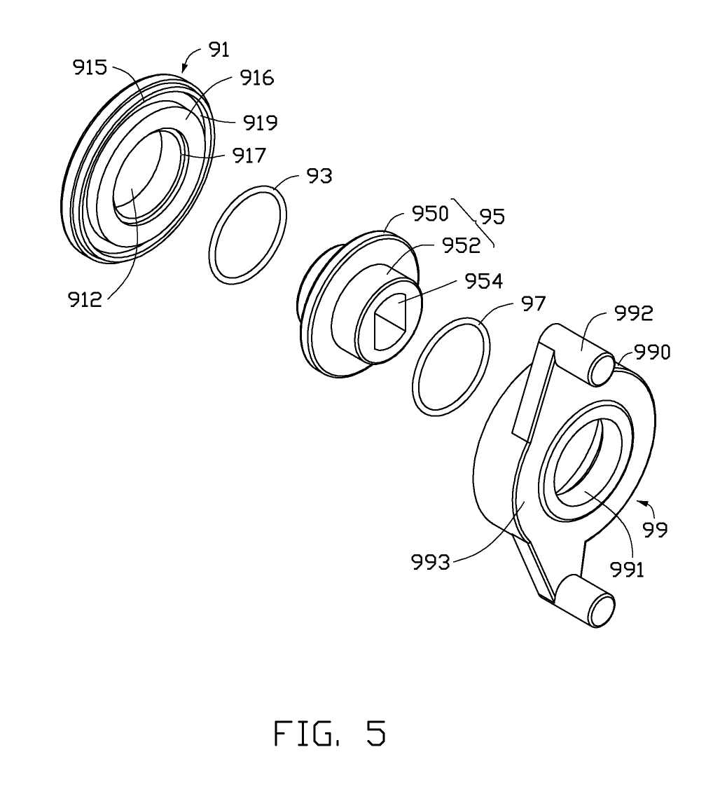

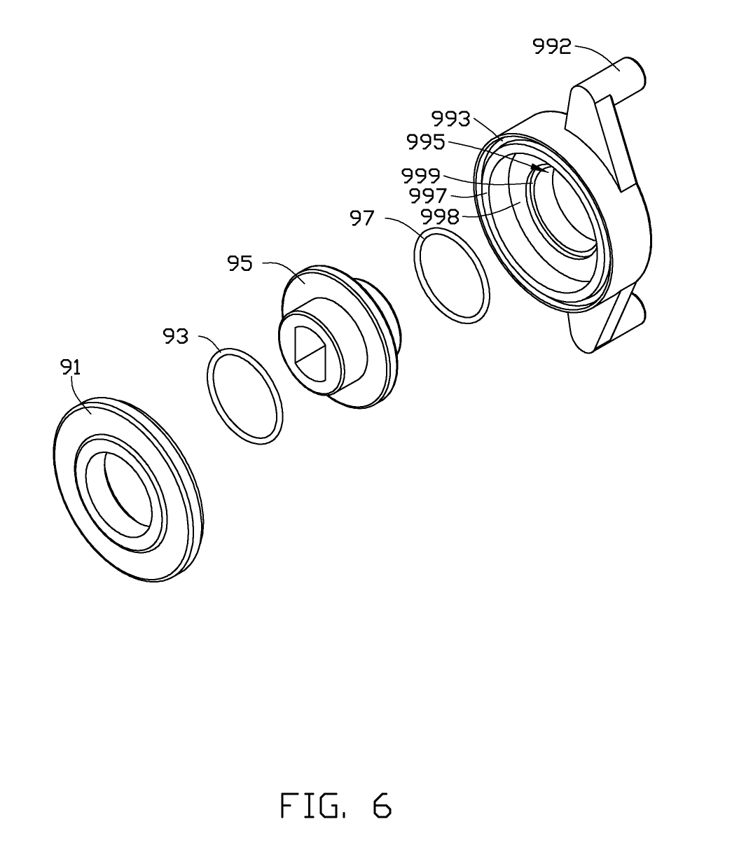

The buffering assemblies 9 is sleeved on the shaft 54 and abut ends of the positioning members 883 away from the pivot bracket 60. Referring to FIGS. 5 and 6, each buffering assembly 9 includes a front cover 91, two gaskets 93, 97, a wheel 95, and a fixing member 99. The front cover 91 is substantially disk shaped. A first protruding ring 916 extends from an end of the front cover 91. The centre of the front cover 91 defines a first receiving hole 912 axially extending through the first protruding ring 916. The first receiving hole 912 rotatably receives the shaft 54, thereby the front cover 91 is rotatably sleeved on the shaft 54. A portion of an inner sidewall of the first protruding ring 916 is removed to define a first step 917. The first step 917 is coaxial with the first protruding ring 916. A second protruding ring 915 further protrudes from the front cover 91. The second protruding ring 915 is coaxial with and spaced apart from the first protruding ring 916, to define a receiving groove 919.

The wheel 95 is sleeved on the shaft 54 and rotates with the shaft 54. The wheel 95 includes a cylinder 952 and a flange 950 protruding from the cylinder 952. The cylinder 952 defines a fixing hole 954 extending longitudinally. The fixing hole 954 fits the shaft 54, to prevent the wheel 95 from rotating with the shaft 54. The diameter of the cylinder 952 is slightly less than the diameter of the first receiving hole 912. The flange 950 is substantially disk shaped, and extends radially outward from the middle of the cylinder 952. The diameter of the flange 950 is equal to the outer diameter of the protruding ring 916.

The fixing member 99 is substantially cylindrical. The fixing member 99 is recessed to define a first groove 993 and a second groove 998. The first groove 993 and the second groove 998 are coaxial. The first groove 993 is spaced apart from the second groove 998, with a ring-shaped engaging portion 997 arranged therebetween. The first groove 993 fits the second protruding ring 915. The second groove 998 fits the first protruding ring 916. The bottom of the second groove 998 is recessed to define a circular recess 995. The bottom of the circular recess 995 further defines a second receiving hole 991 axially extending through the fixing member 99. The diameter of the recess 995 is greater than the diameter of the second receiving hole 991, whereby a second step 999 is formed. The diameter of the second receiving hole 991 is equal to the diameter of the first receiving hole 912. The diameter of the second step 999 is equal to the diameter of the first step 917. Two fixing posts 992 are secured to the sidewall of the fixing member 99. The fixing posts 992 are spaced apart from each other, and correspond to the limiting holes 72.

The gaskets 93, 97 are secured to the first and second steps 917, 999. The diameter of the gaskets 93, 97 is slightly greater than or equal to the diameter of the cylinder 952, thus when ends of the cylinder 952 are received in the first and second receiving holes 912, 991, the joint of the cylinder 952 and the sidewall of the first receiving hole 912, and the joint of the cylinder 952 and the sidewall of the second receiving hole 991 are sealed by the gaskets 93, 96 to avoid leakage of oil or other fluid.

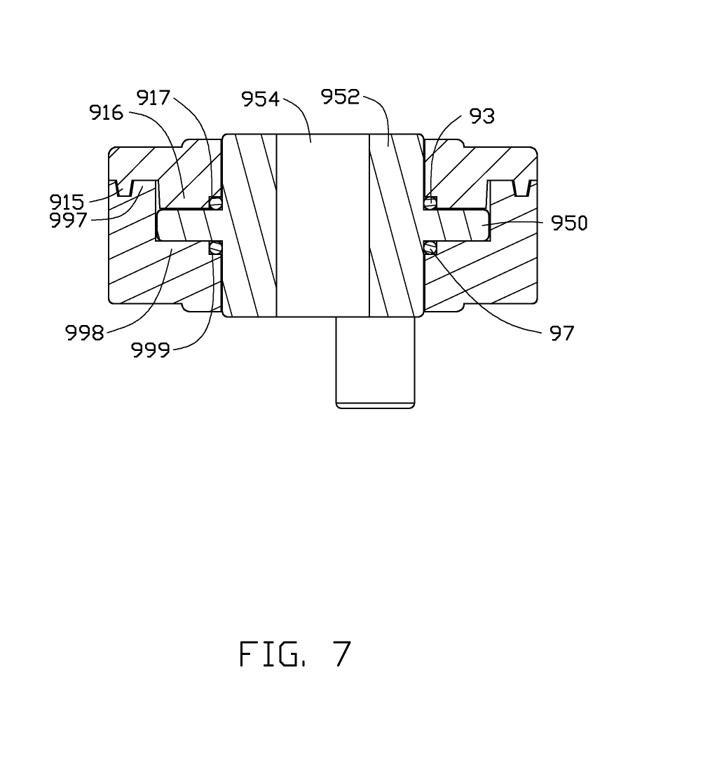

Referring to FIG. 7, in assembly of the buffering assembly 9, first, the gaskets 93, 97 are secured to the first and second steps 917, 999; second, the fixing posts 992 are received in the limiting holes 72; third, an end of the cylinder 952 is inserted into the second receiving hole 991, the other end of the cylinder 952 being inserted into the first receiving hole 912; finally, the front cover 91 resists the wheel 5 against the fixing member 99, and further engages with the second cover 99 with the second protruding ring 915 fitting into the first groove 993 and the first protruding ring 916 fitting into the second groove 998, to define a close space for receiving the flange 950 therein, and the clearance between the front cover 91 and the fixing member 99 is filled with damping oil or fluid for buffering when the wheel 95 rotates with the shaft 54.

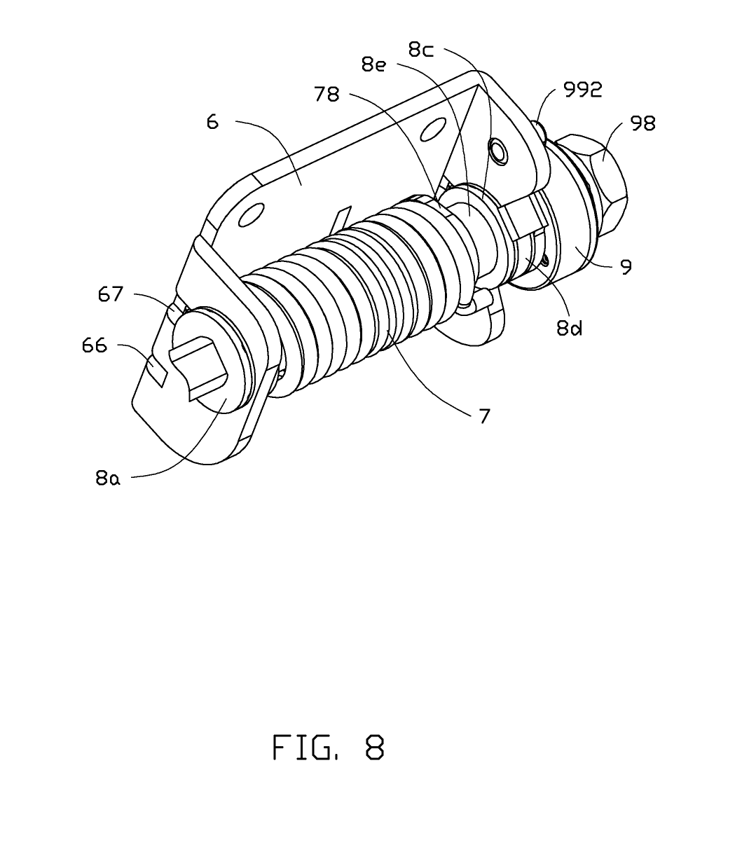

Referring to FIG. 8, after the buffering assembly 9 is assembled, the pivot bracket 60 is fixed to the inner surface 212 of the rear case 20. The elastic member 77 is sleeved on the sleeve 76 with opposite arms 770, 772 being fixed to the first and second latching holes 67, 785. The shafts 54 extend through the fixing hole 954, the positioning assembly 8d, the round hole 70 on the mounting plate 63, the friction assembly 8c, the engaging hole 783, the sleeve 76, the friction assembly 8b, the round hole 65 on the mounting plate 62, the friction assembly 8a in order, and is further fixed to the cantilevers 52. Finally, nuts (not labeled) are threaded to ends of the shaft 54 and abut the buffering assemblies 9.

After assembly, the fixing member 99 is secured to and rotates with the pivot bracket 60, the wheel 95 rotates with the shaft 54, thus, when the shaft 54 rotates with the pivot bracket 60, a frictional force is generated between the wheel 95 and the fixing members 91, 99, to impede free rotation of the shaft 54. Furthermore, the first shim 811 abuts the second shim 813, the first shim 811 rotates with the shaft 54, and the second shim 813 rotates with the pivot bracket 60, thus when the shaft 54 rotates with the pivot bracket 60, another frictional force source is created between the first and second shims 811, 813 to further impede free rotation of the shaft 54. As a result, when the bracket 5 is unfolded, the elastic assembly 7 restores the bracket 5 against the back surface 210 of the rear case 20. At the same time, the buffering assembly 9 and the friction assemblies 8a, 8b, 8c generate frictional forces to slow down the rotation of the shaft 54 relative to the pivot bracket 60, thus the bracket 5 is prevented from abruptly stopping.

Although information as to, and advantages of, the present embodiments have been set forth in the foregoing description, together with details of the structures and functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. A supporting mechanism for supporting a device, comprising:
at least one hinge to be secured to the device, each hinge comprising a pivot bracket to be secured to the device and a shaft rotatably secured to the pivot bracket;
a bracket rotatably fixed to the shaft and to be foldable to the device;
an elastic assembly secured to the at least one hinge and for providing an elastic force to retain the bracket to angle with the device when the bracket is unfolded; and
at least one buffering assembly secured to the shaft, each buffering assembly comprising a fixing member fixed to the pivot bracket and a wheel rotatably secured to the fixing member and rotating with the shaft;
wherein when the bracket is folded, the elastic assembly restores the bracket, the shaft rotates relative to the pivot bracket, the wheel rotates with the shaft and abuts the fixing member to impede free rotation of the shaft.

2. The supporting mechanism of claim 1, wherein the wheel comprises a cylinder rotating with the shaft and a flange extending from the cylinder, the cylinder is rotatably received in the fixing member, and the flange abuts the fixing member.

3. The supporting mechanism of claim 2, wherein each buffering assembly further comprises a front cover, the front cover is rotatably secured to the shaft and is adapted to resist the flange against the fixing member.

4. The supporting mechanism of claim 1, wherein the elastic assembly comprises a sleeve rotatably sleeved on the shaft and an elastic member sleeved on the sleeve, the elastic member comprises a spiral spring and two arms expending from opposite ends of the spiral spring, one of the arms is fixed to the pivot bracket, and the other arm is fixed to the shaft.

5. The supporting mechanism of claim 4, wherein the elastic assembly further comprises a limiting member, the limiting member is secured to the shaft and rotates with the shaft, the other arm is fixed to the limiting member.

6. The supporting mechanism of claim 1, wherein each hinge further comprises at least one friction assembly, each friction assembly comprises a first shim rotating with the shaft and a second shim secured to the pivot bracket, the first shim abuts the second shim to generate a frictional force to further impede free rotation of the shaft.

7. The supporting mechanism of claim 1, wherein each hinge further comprises a positioning assembly for positioning the shaft at two different orientations when the shaft rotates relative to the pivot bracket, when the shaft is switched between the two orientations, the bracket is changeable between a first state folding to the device and a second state unfolded relative to the device.

8. The supporting mechanism of claim 7, wherein the positioning assembly comprises a second shim fixed to the pivot bracket and rotatable relative to the shaft, and a positioning member abutting the second shim and rotating with the shaft.

9. The supporting mechanism of claim 8, wherein the pivot bracket defines two recesses, a positioning post is secured to the positioning member and is capable of sliding between the two recesses, when the shaft rotate relative to the pivot bracket, the positioning post slides between the recesses to position the shaft in the different orientations relative to the pivot bracket.

10. An electronic device comprising:
a main body; and
a supporting mechanism for supporting the main body, the supporting mechanism comprising:
at least one hinge secured to the main body, each hinge comprising a pivot bracket secured to the main body and a shaft rotatably secured to the pivot bracket;
a bracket rotatably fixed to the shaft and foldable to the main body;
an elastic assembly secured to the at least one hinge and for providing an elastic force to retain the bracket angling with the main body when the bracket is unfolded; and
at least one buffering assembly secured to the shaft, each buffering assembly comprising a fixing member fixed to the pivot bracket and a wheel rotatably secured to the fixing member and rotating with the shaft;
wherein when the bracket is folded, the elastic assembly restores to rebound the bracket, the shaft rotates relative to the pivot bracket, the wheel rotates with the shaft and abuts the fixing member to impede free rotation of the shaft.

11. The electronic device of claim 10, wherein the wheel comprises a cylinder rotating with the shaft and a flange extending from the cylinder, the cylinder is rotatably received in the fixing member, and the flange abuts the fixing member.

12. The electronic device of claim 11, wherein each buffering assembly further comprises a front cover, the front cover is rotatably secured to the shaft and is adapted to resist the flange against the fixing member.

13. The electronic device of claim 10, wherein the elastic assembly comprises a sleeve rotatably sleeved on the shaft and an elastic member sleeved on the sleeve, the elastic member comprise a spiral spring and two arms expending from opposite ends of the spiral spring, one of the arms is fixed to the pivot bracket, and the other arm is fixed to the shaft.

14. The electronic device of claim 13, wherein the elastic assembly further comprises a limiting member, the limiting member is secured to the shaft and rotates with the shaft, the other arm is fixed to the limiting member.

15. The electronic device of claim 10, wherein each hinge further comprises at least one friction assembly, each friction assembly comprises a first shim rotating with the shaft and a second shim secured to the pivot bracket, the first shim abuts the second shim to generate a frictional force to further impede free rotation of.

16. The electronic device of claim 10, wherein each hinge further comprises a positioning assembly for positioning the shaft at two different orientations when the shaft rotates relative to the pivot bracket, when the shaft is switched between the two orientations, the bracket is changeable between a first state folding to the main body and a second state unfolded relative to the main body.

17. The electronic device of claim 16, wherein the positioning assembly comprises a second shim fixed to the pivot bracket and rotatable relative to the shaft, and a positioning member abutting the second shim and rotating with the shaft.

18. The electronic device of claim 17, wherein the pivot bracket defines two recesses, a positioning post is secured to the positioning member and is capable of sliding between the two recesses, when the shaft rotate relative to the pivot bracket, the positioning post slides between the recesses to position the shaft in the different orientations relative to the pivot bracket.
